(19) United States
(12) Patent Application Publication
(10) Pub. No.: US 2026/0107395 A1
(43) Pub. Date: Apr. 16, 2026

(54) DIGITAL PHOTO FRAME

(71) Applicant: Shenzhen Joyhong Tech Co.,Ltd, Shenzhen (CN)

(72) Inventor: Jianping Wang, Shenzhen (CN)

(21) Appl. No.: 19/421,399

(22) Filed: Dec. 16, 2025

(30) Foreign Application Priority Data
Nov. 28, 2025 (CN) 202522533642.4

(51) Int. Cl. H05K 5/02; H04R 1/02; H05K 5/03

(52) U.S. Cl. CPC H05K 5/0217; H04R 1/025; H04R 1/028; H05K 5/03; H04R 2420/09; H04R 2499/15

(57) ABSTRACT

A digital photo frame is provided, belonging to the technical field of digital products, including a housing, wherein the housing is provided with a first concave installation position on a front side thereof, a middle frame being engaged inside the first concave installation position, and a digital display screen being installed inside the middle frame; and wherein the housing is provided with a second concave installation position on a back side thereof, a back shell being engaged inside the second concave installation position, the back shell being formed with a plurality of magnet installation slots on an inner side thereof, and magnets being embedded in the magnet installation slots.

### TECHNICAL FIELD

The present disclosure relates to the technical field of digital products, more particularly to a digital photo frame.

### BACKGROUND

At present, as a common electronic product in daily life, digital photo frames available on the market are appearing in an increasing number of types. However, current digital photo frames still have some shortcomings in structural assembly and installation.

Current digital photo frames have their housings, middle frames and back shells connected employing screws or simple snap-fit connection. The assembly is tedious, with poor firmness. They are prone to fall off after long-term usage, which increases the difficulty of production and maintenance. In addition, elements such as main control boards and speakers have no dedicated positioning structures, and wrong installation is easy to occur, affecting the stability of electrical connection.

Current digital photo frames have a relatively single fixing mode; their fixing merely depends on hanging holes or brackets, and they cannot be quickly adsorbed and fixed onto a surface of a metal article such as fridge. The usage scenarios are limited, and the flexibility of usage is greatly reduced. Meanwhile, the screen cover plate has a poor protective effect for the digital display screen, shortening the service life of the product.

### SUMMARY

It is an object of the present disclosure to provide a digital photo frame to address the problems mentioned in the above background.

To achieve the above object, the present disclosure provides a technical scheme as follows. A digital photo frame includes a housing, wherein the housing is provided with a first concave installation position on a front side thereof, a middle frame being engaged inside the first concave installation position, and a digital display screen being installed inside the middle frame; wherein the housing is provided with a second concave installation position on a back side thereof, a back shell being engaged inside the second concave installation position, the back shell being formed with a plurality of magnet installation slots on an inner side thereof, magnets being embedded in the magnet installation slots, and an inside of the back shell being provided with a mainboard installation position in which a main control board is installed; wherein the back shell is provided with two speaker installation positions in both of which speakers are installed, the back shell being formed with a recess on a back side thereof directly opposite to the main control board, the recess being provided with cable passing grooves on a side and a bottom thereof, and the back shell being formed with two sound outlets on a back side thereof directly opposite to the two speakers; and wherein the recess is formed with a type-c port and a DC power port on an inner side thereof, the type-c port and the DC power port corresponding to positions of a type-c socket and a DC power socket of the main control board respectively.

In a preferred embodiment of the present disclosure, the middle frame is installed with a screen cover plate on an outer side thereof through a plurality of connectors, an edge of the screen cover plate being engaged with a top of the first concave installation position.

In a preferred embodiment of the present disclosure, the first concave installation position has an inner side fixedly connected to a plurality of first elastic protrusions, the first elastic protrusions being engaged with first slots formed on an outer side of the middle frame.

In a preferred embodiment of the present disclosure, the second concave installation position has an inner side connected to a plurality of second elastic protrusions, the second elastic protrusions being engaged with second slots formed on an outer side of the back shell.

In a preferred embodiment of the present disclosure, the inside of the back shell is further fixedly connected to a plurality of reinforcement ribs, the plurality of reinforcement ribs being distributed in a diamond grid pattern.

In a preferred embodiment of the present disclosure, the back side of the back shell is formed with triangular hanging holes both widthwise and lengthwise, a middle part on the back side of the back shell being formed with a plurality of bracket installation holes.

Compared to existing technologies, the present disclosure has the following beneficial effects.

Through the engagement of the first concave installation position of the housing and the middle frame and the engagement of the second concave installation position and the back shell, specifically, through the engagement of the first elastic protrusions and the first slots of the middle frame and the engagement of the second elastic protrusions and the second slots, each component of the present disclosure can be assembled firmly and disassembled conveniently, improving the assembly and maintenance efficiency. The mainboard installation position and the speaker installation positions on the back shell can accurately position the main control board and the speakers, ensuring the stability of element installation and the reliability of electrical connection. The cable passing grooves formed in the recess can tidy up and protect cables. The type-c port and the DC power port can meet different requirements of power supply and data transmission; and the sound outlets can guarantee good propagation of sound.

The magnets in the magnet installation slots on the back shell can be directly adhered to a fridge or other metal articles, achieving fast fixing of the digital photo frame, overcoming the limitation of conventional installations depending merely on hanging holes and brackets, greatly expanding the usage scenarios, and enhancing the convenience of usage. In addition, the screen cover plate mounted on the outer side of the middle frame through connectors has the edge engaged with the top of the first concave installation position, which effectively enhances the protection for the digital display screen. The reinforcement ribs distributed in a diamond grid pattern inside the back shell can enhance the structural strength. The triangular hanging holes and the plurality of bracket installation holes on the back side of the back shell can further meet the requirements of diversified installations. Therefore, the problems of inconvenient structure assembly, unfirm element installation and single installation mode in existing technologies are completely solved.

### BRIEF DESCRIPTION OF THE DRAWINGS

FIG. 1 is a structure diagram of the present disclosure.

FIG. 2 is one of the structure diagrams of the present disclosure.

FIG. 3 is an enlargement view of part A in FIG. 2 of the present disclosure.

FIG. 4 is an exploded view of the present disclosure.

FIG. 5 is a structure diagram of a first concave installation position of the present disclosure.

FIG. 6 is a structure diagram of a second concave installation position of the present disclosure.

FIG. 7 is a structure diagram of a back shell of the present disclosure.

In the drawings: 100, housing; 110, first concave installation position; 111, first elastic protrusion; 112, digital display screen; 120, second concave installation position; 121, second elastic protrusion; 200, middle frame; 210, connector; 220, screen cover plate; 230, first slot; 300, back shell; 310, magnet installation slot; 320, magnet; 330, mainboard installation position; 340, main control board; 350, speaker installation position; 360, speaker; 370, recess; 371, type-c port; 372, DC power port; 380, cable passing groove; 390, sound outlet; 3110, second slot; 3120, reinforcement rib; 3130, triangular hanging hole; 3140, bracket installation hole.

### DETAILED DESCRIPTION OF THE EMBODIMENTS

The purpose, the technical scheme and the advantages of the embodiments of the present disclosure will become more clearly understood from the clear and complete description of the technical scheme of the embodiment of the present disclosure below taken in conjunction with the accompanying drawings in the present disclosure. Apparently, the embodiments described hereinafter are simply part embodiments of the present disclosure, rather than all of the embodiments. All other embodiments obtained by those ordinary skilled in the art based on the embodiments of the present disclosure without creative work are intended to be included in the scope of protection of the present disclosure.

### Embodiment 1

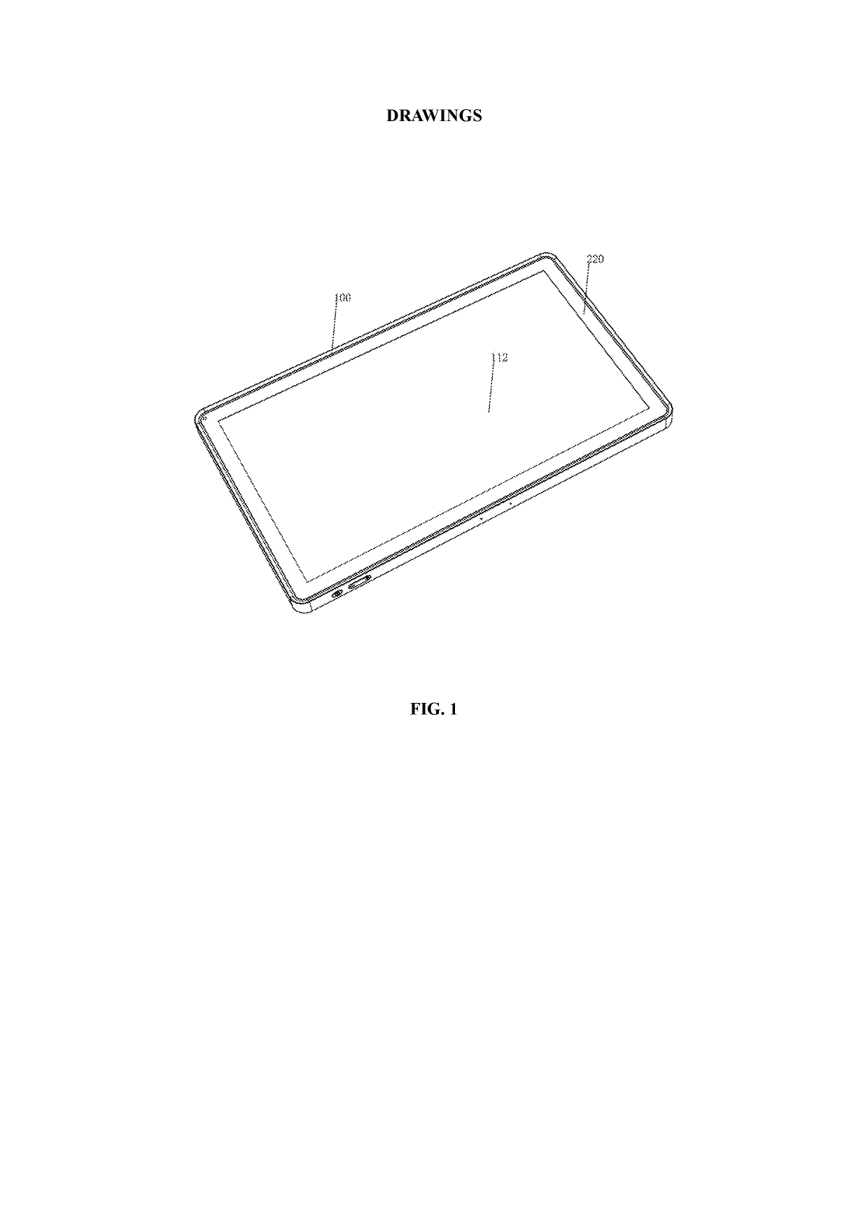

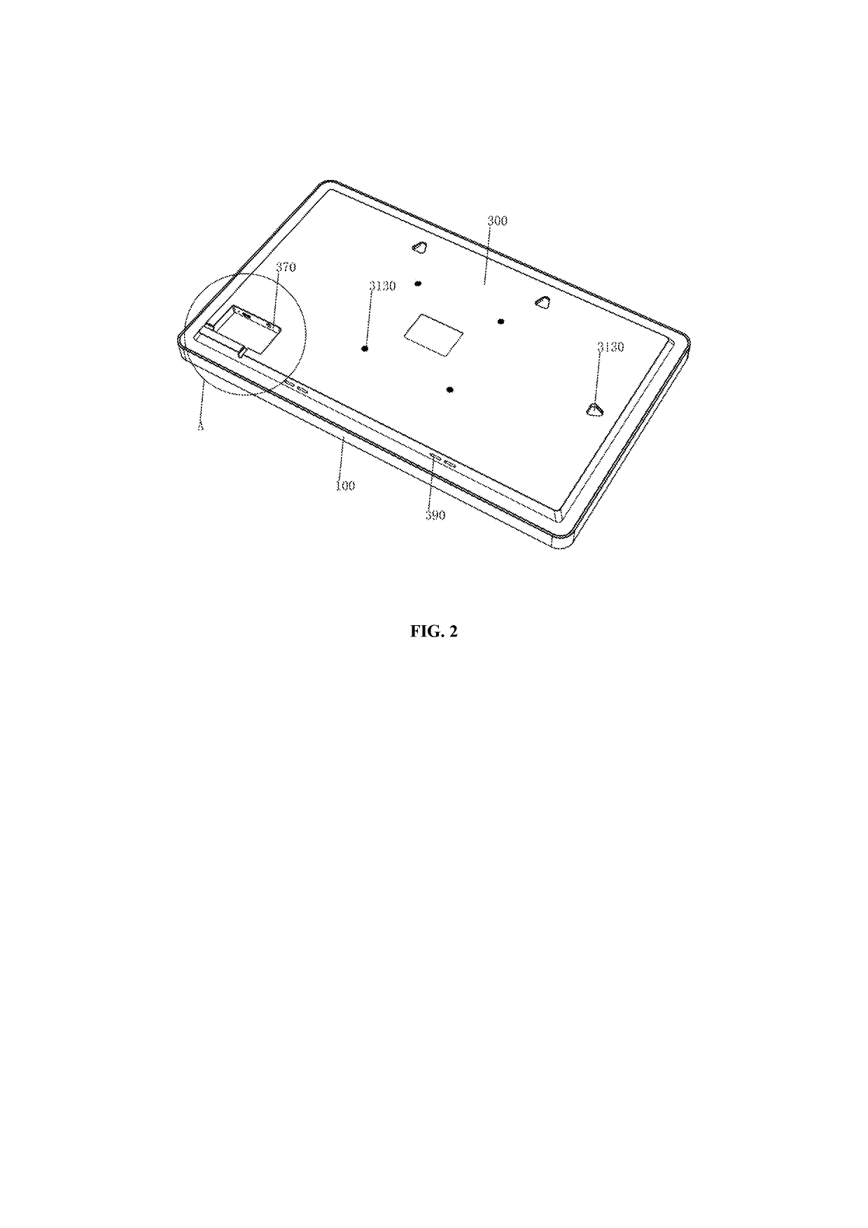

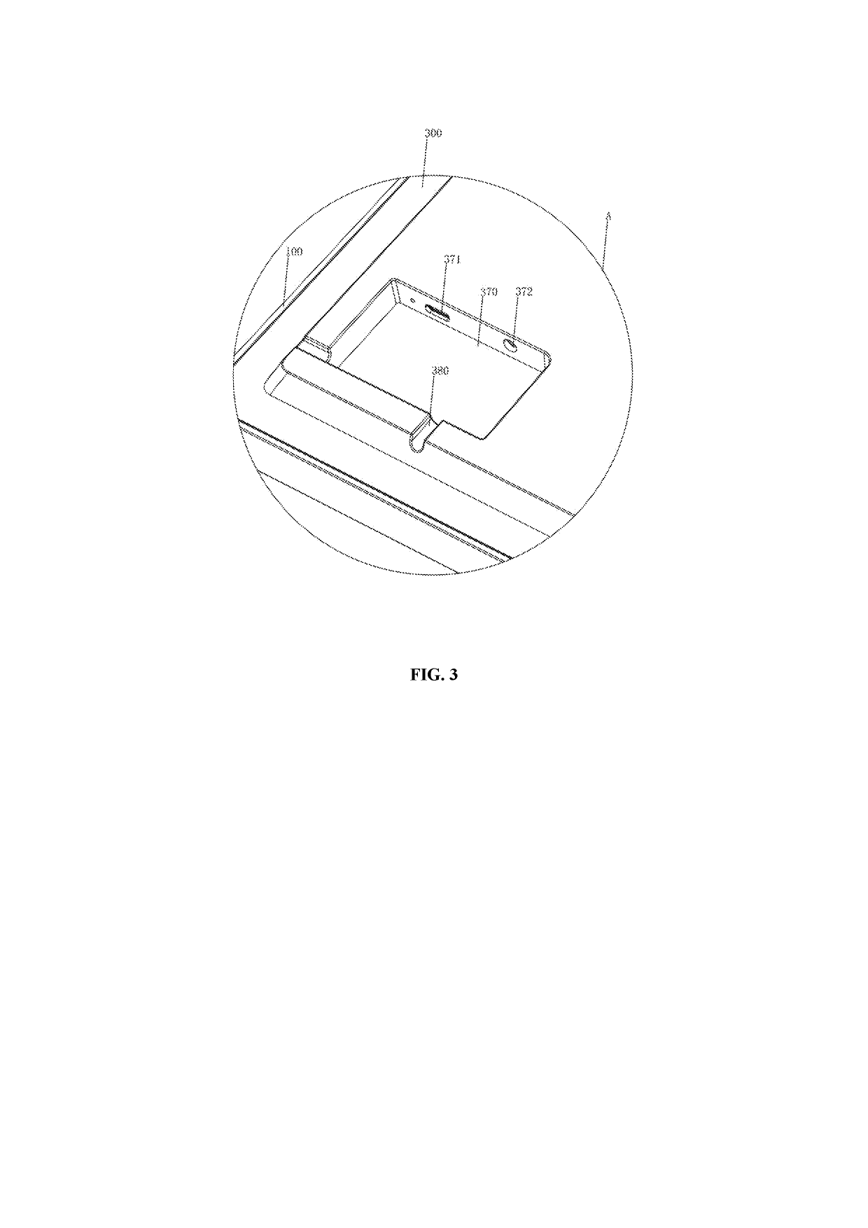

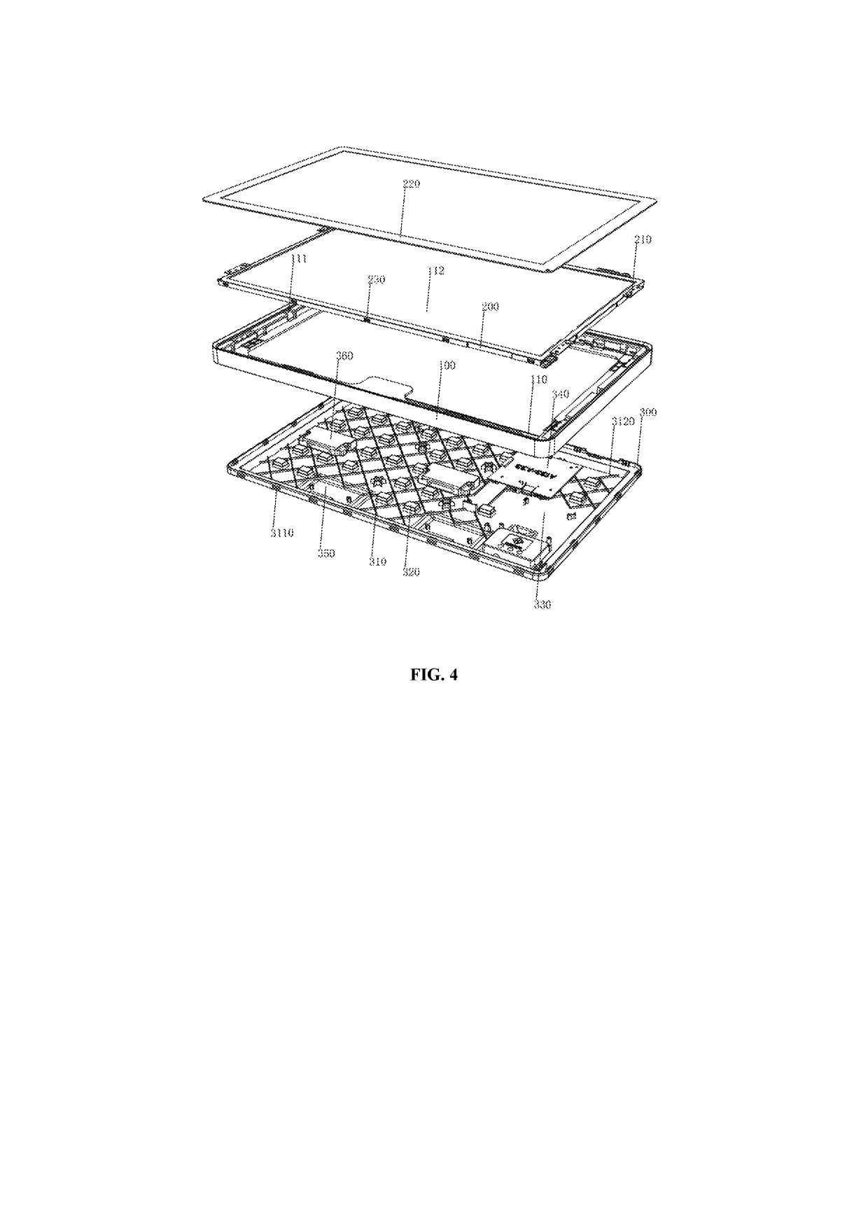

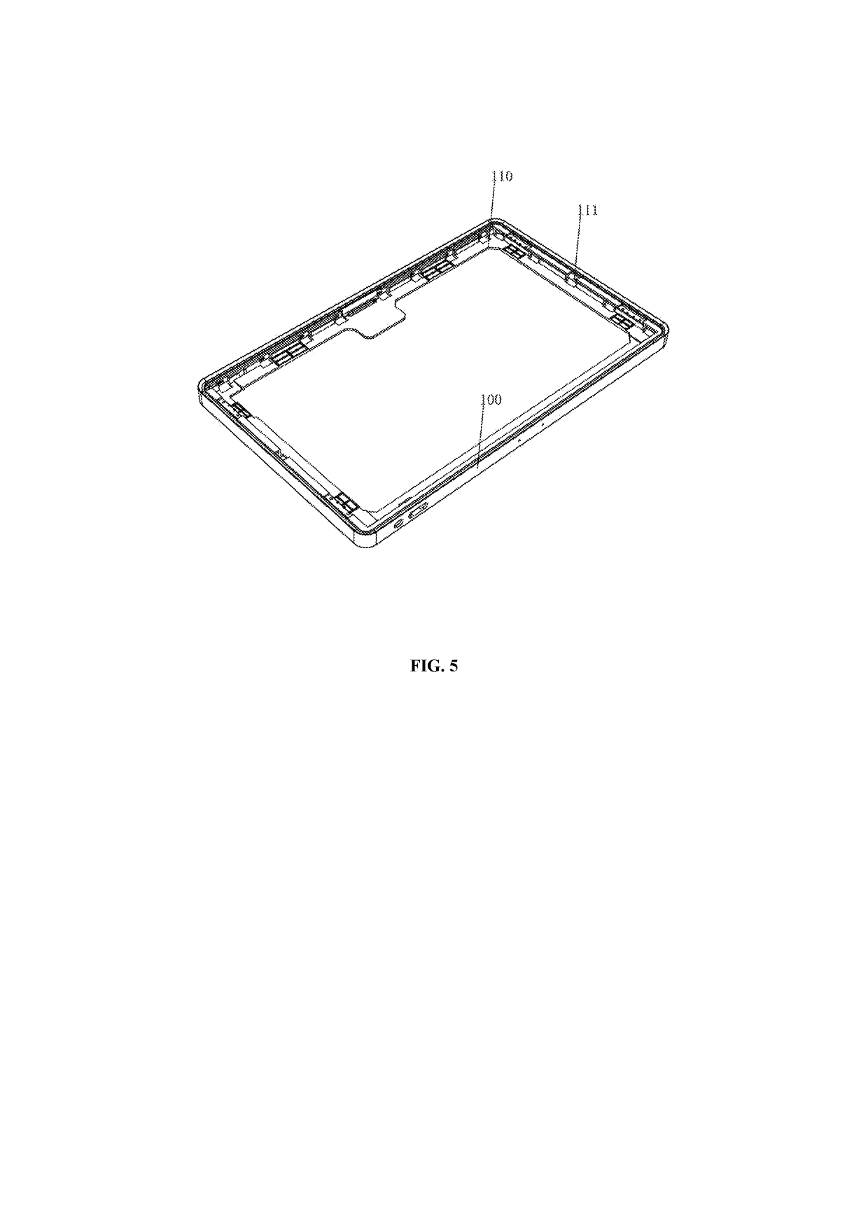

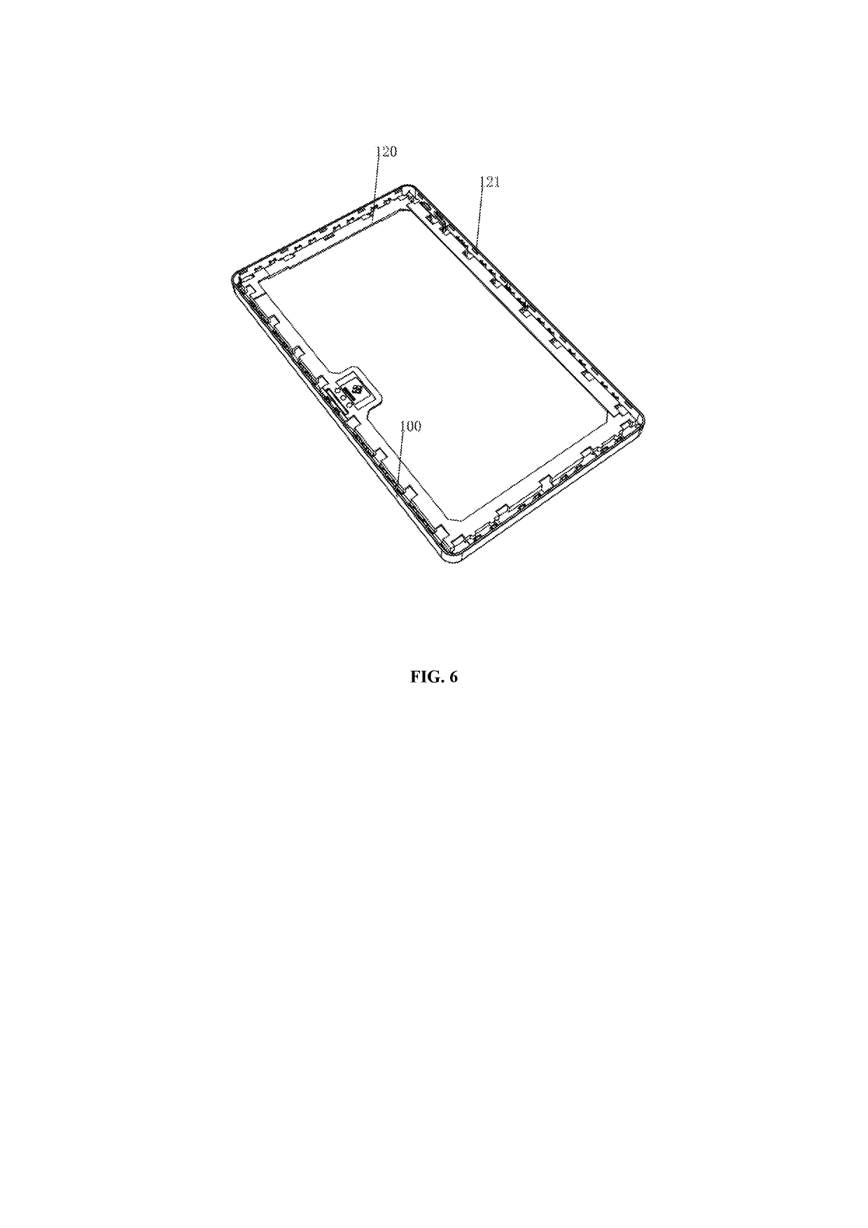

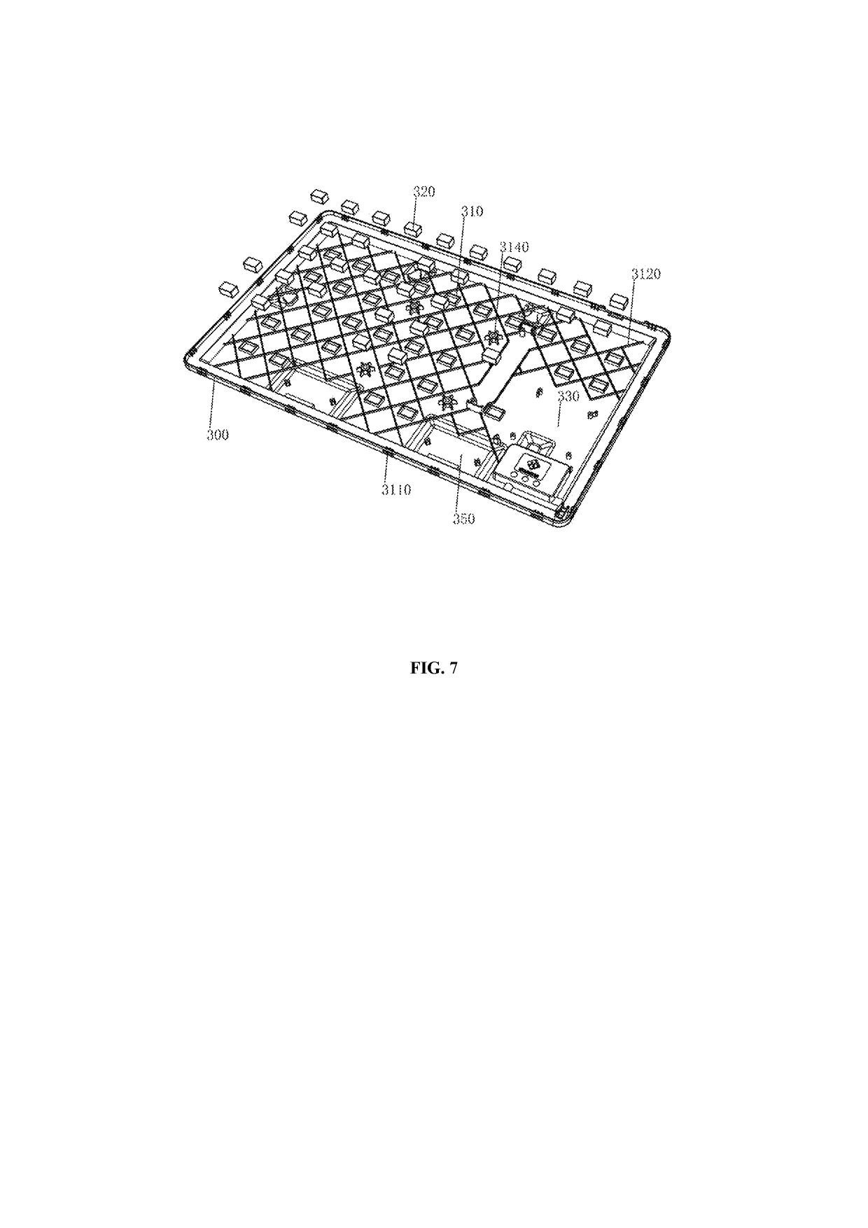

Referring to FIG. 1 to FIG. 7, a digital photo frame includes a housing 100, wherein the housing 100 is provided with a first concave installation position 110 on a front side thereof, a middle frame 200 being engaged inside the first concave installation position 110, and a digital display screen 112 being installed inside the middle frame 200; wherein the housing 100 is provided with a second concave installation position 120 on a back side thereof, a back shell 300 being engaged inside the second concave installation position 120, the back shell 300 being formed with a plurality of magnet installation slots 310 on an inner side thereof, magnets 320 being embedded in the magnet installation slots 310, and an inside of the back shell 300 being provided with a mainboard installation position 330 in which a main control board 340 is installed; wherein the back shell 300 is provided with two speaker installation positions 350 in both of which speakers 360 are installed, the back shell 300 being formed with a recess 370 on a back side thereof directly opposite to the main control board 340, the recess 370 being provided with cable passing grooves 380 on a side and a bottom thereof, and the back shell 300 being formed with two sound outlets 390 on a back side thereof directly opposite to the two speakers 360; and wherein the recess 370 is formed with a type-c port 371 and a DC power port 372 on an inner side thereof, the type-c port 371 and the DC power port 372 corresponding to positions of a type-c socket and a DC power socket of the main control board 340 respectively.

Specifically, when the digital photo frame is being assembled and in daily use, the housing 100 serves as a basic carrier of the whole structure, the first concave installation position 110 on the front side thereof provides an accurate embedding space for the middle frame 200. When the middle frame 200 is embedded into first concave installation position 110, the inside digital display screen 112 can achieve a stable display function, allowing users to clearly watch the content. After the front side is assembled, the second concave installation position 120 on the back side of the housing 100 will engage with the back shell 300, and the magnets 320 embedded into the magnet installation slots 310 on the inner side of the back shell 300 can offer magnetic adhesion.

If a user wants to fix the photo frame onto a surface of a metal object such as fridge, he/she just needs to make the back shell 300 face the metal surface, then the magnets 320 can finish fast fixation through magnetic adhesion, with no need for extra tools. The mainboard installation position 330 on the back shell 300 can achieve accurate positioning of the main control board 340, ensuring stable electrical connection between the main control board 340 and the digital display screen 112 and the speakers 360. The two speaker installation positions 350 on the back shell 300 can keep the speakers 360 fixed in place, avoiding displacement resulting from vibration to affect the sound effect.

When a user needs to charge the digital photo frame or upload data, the type-c port 371 inside the recess 370 on the back side of the back shell 300 can be connected to a data line, the DC power port 372 can be connected to an adapter, and the cable passing grooves 380 on the side and bottom of the recess 370 can be used to tidy up and contain cables, preventing disorder and entanglement. The sound outlets 390 on the back side of the back shell 300 directly opposite to the speakers 360 can smoothly propagate the sound of the speakers 360. Through this structure design, the photo frame is stable and efficient in both assembly and usage.

In the present embodiment, the middle frame 200 is installed with a screen cover plate 220 on an outer side thereof through a plurality of connectors 210, and an edge of the screen cover plate 220 is engaged with a top of the first concave installation position 110.

Specifically, when the screen of the digital photo frame is being assembled and in daily protection, the middle frame 200 serves as a direct carrier structure for the digital display screen 112, and the plurality of connectors 210 on the outer side can achieve a firm connection with the screen cover plate 220. When in assembly, it is only required to fix the screen cover plate 220 to the outer side of the middle frame 200 through the connectors 210, thereby adding a protective shield to the inside digital display screen 112. After the screen assembly, the edge of the screen cover plate 220 is engaged with the top of the first concave installation position 110 on the front side of the housing 100, not only forming a seamless look between the screen cover plate 220 and the housing 100, but also being able to prevent dust and water stain entering the middle frame 200 to contact the digital display screen 112 in daily usage, and meanwhile buffering the impact force from an external slight collision, avoiding direct damage to the digital display screen 112, and effectively prolonging the service life of the digital display screen 112.

In the present embodiment, the first concave installation position 110 has an inner side fixedly connected to a plurality of first elastic protrusions 111, the first elastic protrusions 111 being engaged with first slots 230 formed on an outer side of the middle frame 200.

Specifically, when a user is assembling the middle frame 200 and the housing 100, the plurality of first elastic protrusions 111 on the inner side of the first concave installation position 110 on the front side of the housing 100 can form accurate engagement with the first slots 230 on the outer side of the middle frame 200. During specific operation, a user just needs to align the middle frame 200 to the first concave installation position 110 and then gently push in, and the first elastic protrusions 111 are elastically deformed due to the squeeze by the middle frame 200; when the middle frame 200 is pushed in place, the first elastic protrusions 111 restore and are embedded into the first slots 230 of the middle frame 200, accomplishing a firm connection therebetween, with no need for tools such as screws, greatly simplifying the assembly process and improving the production or maintenance efficiency.

In daily usage, when a user is moving the digital photo frame, the engagement state between the first elastic protrusions 111 and the first slots 230 can resist the risk of loosening caused by vibration, avoiding the middle frame 200 falling off from the first concave installation position 110, and ensuring the stable installation of the digital display screen 112 inside the middle frame 200. Even if the photo frame needs to be disassembled and maintained after long-term usage, it only requires gently prying up the middle frame 200, where the first elastic protrusions 111 are deformed again to disengage from the first slots 230, achieving easy disassembly, and allowing a firm and flexible connection between the middle frame 200 and the housing 100.

In the present embodiment, the second concave installation position 120 has an inner side connected to a plurality of second elastic protrusions 121, the second elastic protrusions 121 being engaged with second slots 3110 formed on an outer side of the back shell 300.

Specifically, during the assembly and subsequent usage processes of the back shell 300 and the housing 100, the plurality of second elastic protrusions 121 on the inner side of the second concave installation position 120 on the back side of the housing 100 can form efficient engagement with the second slots 3110 on the outer side of the back shell 300. When a user aligns the back shell 300 to the second concave installation position 120 and pushes in, the second elastic protrusions 121 are squeezed by the edge of the back shell 300 to generate elastic contraction. When the back shell 300 is completely pushed in place, the second elastic protrusions 121 restore to the original state and are embedded into the second slots 3110 of the back shell 300, quickly accomplishing the firm connection therebetween, thereby saving the tedious steps of screwing fixing.

In daily usage, when a user adheres the photo frame to a fridge by means of the magnets 320 on the back shell 300, the back shell 300 will be subjected to a combined effect of adsorption force and its own gravity, at this time the engagement structure of the second elastic protrusions 121 and the second slots 3110 can limit the displacement of the back shell 300, avoiding it falling off from the second concave installation position 120, and ensuring the stable installation of the main control board 340, the speakers 360 and other elements inside the back shell 300.

When to inspect the internal elements of the photo frame, it is only needed to pull the back shell 300 outward, where the second elastic protrusions 121 are deformed to disengage from the second slots 3110, achieving easy disassembly, thereby enabling convenient and reliable disassembly of the back shell 300.

In the present embodiment, the inside of the back shell 300 is further fixedly connected to a plurality of reinforcement ribs 3120, the plurality of reinforcement ribs 3120 being distributed in a diamond grid pattern.

Specifically, when assembling the digital photo frame, the reinforcement ribs 3120 distributed in a diamond grid pattern can provide a uniform support force for an inner wall of the back shell 300, avoiding a partial concave deformation of the back shell 300 due to the weight of the elements, and ensuring the accuracy of the element installation position. During practical usage, when a user adheres the photo frame to a side wall of a fridge by means of the magnets 320, the back shell 300 will be subjected to a lateral adsorption force and a longitudinal gravity, then the reinforcement ribs 3120 of the diamond grid pattern structure can scatter the stress to every area of the back shell 300, avoiding local stress being concentrated to lead to deformation. If the photo frame is slightly hit accidentally, the reinforcement ribs 3120 can buffer the impact force, reducing the degree of deformation of the back shell 300, enhancing the structural strength of the back shell 300 multi-dimensionally, maintaining a stable shape after long-term usage, and providing a continuous safe loading environment for internal elements.

In the present embodiment, the back side of the back shell 300 is formed with triangular hanging holes 3130 both widthwise and lengthwise, a middle part on the back side of the back shell 300 being formed with a plurality of bracket installation holes 3140.

Specifically, if a user does not want to choose the adhesion of magnets 320, but choose hanging installation, with the widthwise and lengthwise triangular hanging holes 3130 on the back side of the back shell 300, the user can make hooks pass through the triangular hanging holes 3130 in a corresponding direction according to the installation space. The triangular structure can enhance the firmness of hanging installation, avoiding the photo frame failing off due to slight shaking, and being suitable for hanging on living room walls, vestibules and other scenarios.

When a user expects to place the photo frame onto planes such as table surface or bedside table, the user can align the connectors of a mated bracket to the plurality of bracket installation holes 3140 in the middle part of the back side of the back shell 300 for fixation. The layout of the plurality of bracket installation holes 3140 can adapt to brackets of different heights and angles, meeting the user’s requirement in adjusting display angle of view. After the bracket is fixed through the bracket installation holes 3140, the user can adjust the angle of the photo frame to obtain a comfortable view. The design of making the photo frame adaptable to multiple scenarios such as hanging installation and bracket placement significantly improves the flexibility of usage.

It should be noted that relational terms such as “first”, “second”, etc. in this paper are used only for distinguishing one entity or operation from another entity or operation, and are not necessarily used for demanding or implying any actual relationship or precedence order between these entities or operations. In addition, the term “comprise”, “include” or any other variation thereof mean “including, but not limited to”, so that a process, method, article or equipment comprising a series of elements not only includes those listed elements, but also includes other elements that are not clearly listed, or also includes elements that are inherent for this process, method, article or equipment.

The content not described in detail in the specification belongs to the prior art known to those skilled in the art. Although the present disclosure has been described in detail by reference to the above-mentioned embodiments, for those skilled in the art, modifications also can be made to the technical scheme recorded in each embodiment mentioned above, or partial technical features can be substituted equivalently. Any modifications, equivalent substitutes and improvements, etc., made within the spirit and principle of the present disclosure all are included in the protection scope of the present disclosure.

What is claimed is:

1. A digital photo frame, comprising a housing (100), wherein the housing (100) is provided with a first concave installation position (110) on a front side thereof, a middle frame (200) being engaged inside the first concave installation position (110), and a digital display screen (112) being installed inside the middle frame (200); wherein the housing (100) is provided with a second concave installation position (120) on a back side thereof, a back shell (300) being engaged inside the second concave installation position (120), the back shell (300) being formed with a plurality of magnet installation slots (310) on an inner side thereof, magnets (320) being embedded in the magnet installation slots (310), and an inside of the back shell (300) being provided with a mainboard installation position (330) in which a main control board (340) is installed; wherein the back shell (300) is provided with two speaker installation positions (350) in both of which speakers (360) are installed, the back shell (300) being formed with a recess (370) on a back side thereof directly opposite to the main control board (340), the recess (370) being provided with cable passing grooves (380) on a side and a bottom thereof, and the back shell (300) being formed with two sound outlets (390) on a back side thereof directly opposite to the two speakers (360); and wherein the recess (370) is formed with a type-c port (371) and a DC power port (372) on an inner side thereof, the type-c port (371) and the DC power port (372) corresponding to positions of a type-c socket and a DC power socket of the main control board (340) respectively.

2. The digital photo frame according to claim 1, wherein the middle frame (200) is installed with a screen cover plate (220) on an outer side thereof through a plurality of connectors (210), an edge of the screen cover plate (220) being engaged with a top of the first concave installation position (110).

3. The digital photo frame according to claim 1, wherein the first concave installation position (110) has an inner side fixedly connected to a plurality of first elastic protrusions (111), the first elastic protrusions (111) being engaged with first slots (230) formed on an outer side of the middle frame (200).

4. The digital photo frame according to claim 1, wherein the second concave installation position (120) has an inner side connected to a plurality of second elastic protrusions (121), the second elastic protrusions (121) being engaged with second slots (3110) formed on an outer side of the back shell (300).

5. The digital photo frame according to claim 1, wherein the inside of the back shell (300) is further fixedly connected to a plurality of reinforcement ribs (3120), the plurality of reinforcement ribs (3120) being distributed in a diamond grid pattern.

6. The digital photo frame according to claim 1, wherein the back side of the back shell (300) is formed with triangular hanging holes (3130) both widthwise and lengthwise, a middle part on the back side of the back shell (300) being formed with a plurality of bracket installation holes (3140).
